(19) United States
(12) Patent Application Publication
(10) Pub. No.: US 2025/0203940 A1
(43) Pub. Date: Jun. 19, 2025

(54) Profiles Of Gate Structures In Semiconductor Devices

(71) Applicant: Taiwan Semiconductor Manufacturing Company, Ltd., Hsinchu (TW)

(72) Inventors: Shao-Hua HSU, Taitung City (TW); Chia-I Lin, Taipei City (TW); Kai-Min CHIEN, Hsinchu (TW); Yuan-Cheng HU, Taichung City (TW); Yu-Jiun PENG, Hsinchu (TW); Kuo-Chin LIU, Haulien (TW); Ryan Chia-Jen CHEN, Hsinchu (TW)

(73) Assignee: Taiwan Semiconductor Manufacturing Company, Ltd., Hsinchu (TW)

(21) Appl. No.: 18/740,894

(22) Filed: Jun. 12, 2024

Related U.S. Application Data
(60) Provisional application No. 63/609,616, filed on Dec. 13, 2023.

(51) Int. Cl. H01L 29/423; H01L 29/06; H01L 29/66; H01L 29/775; H01L 29/786

(52) U.S. Cl. CPC H10D 30/6735; H10D 30/014; H10D 30/031; H10D 30/43; H10D 30/6757; H10D 62/121; H10D 64/017

(57) ABSTRACT

A semiconductor device and a method of fabricating the semiconductor device are disclosed. The semiconductor device includes a substrate, a semiconductor layer disposed on the substrate, a source/drain region disposed adjacent to the semiconductor layer, a gate structure disposed on the semiconductor layer, an interfacial spacer layer having a triangular cross-sectional profile disposed along sidewall of the gate structure, and a gate spacer. The gate spacer includes a first spacer portion having a first bottom surface with a substantially linear profile disposed on the semiconductor layer and a second spacer portion having a second bottom surface with a sloped profile disposed on the interfacial spacer layer.

### CROSS-REFERENCE TO RELATED APPLICATIONS

This application claims the benefit of U.S. Provisional Patent Application No. 63/609,616, titled “Metal Gate Profiles in Semiconductor Devices,” filed Dec. 13, 2023, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1 illustrates an isometric view of a semiconductor device, in accordance with some embodiments.

FIGS. 1B-1E and 2 illustrate different cross-sectional views of a semiconductor device with interfacial spacer layers, in accordance with some embodiments.

FIG. 3 is a flow diagram of a method for fabricating a semiconductor device with interfacial spacer layers, in accordance with some embodiments.

FIGS. 4-20 illustrate cross-sectional views of a semiconductor device with interfacial spacer layers at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The present disclosure provides example structures and methods for improving bottom corner profiles of gate structures in FETs to prevent current leakage between gate structures and source/drain (S/D) regions in the FETs. In some embodiments, a FET can have nanostructured channel regions disposed on a substrate, a gate structure disposed around the nanostructured channel regions, S/D regions disposed adjacent to the nanostructured channel regions, and outer gate spacers disposed along sidewalls of the gate structure to electrically isolate the gate structure from adjacent source/drain regions. In some embodiments, interfacial gaps can exist between the outer gate spacers and the topmost nanostructured channel regions. These interfacial gaps can be filled with interfacial spacer layers having an insulating material. The interfacial spacer layers can prevent bottom corner portions of the gate structure from being formed in the interfacial gaps during the formation of the gate structure. Preventing bottom corner portions of the gate structure from extending under the outer gate spacers can increase the spacing between the gate structure and adjacent S/D regions, prevent current leakage or minimize the probability of current leakage between the gate structure and adjacent S/D regions, and improve device performance. Thus, with the use of interfacial spacer layers, the bottom corner profiles of the gate structure can be controlled. Depending on the sidewall profiles of the interfacial spacer layers, the gate structure can have a U-shaped cross-sectional profile with bottom corners having right-angled corner profiles, beveled corner profiles, or rounded corner profiles.

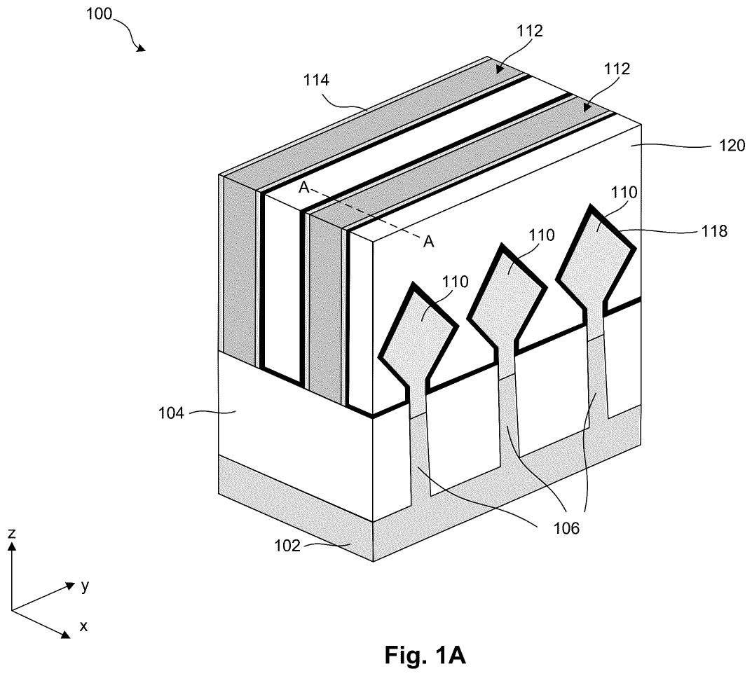

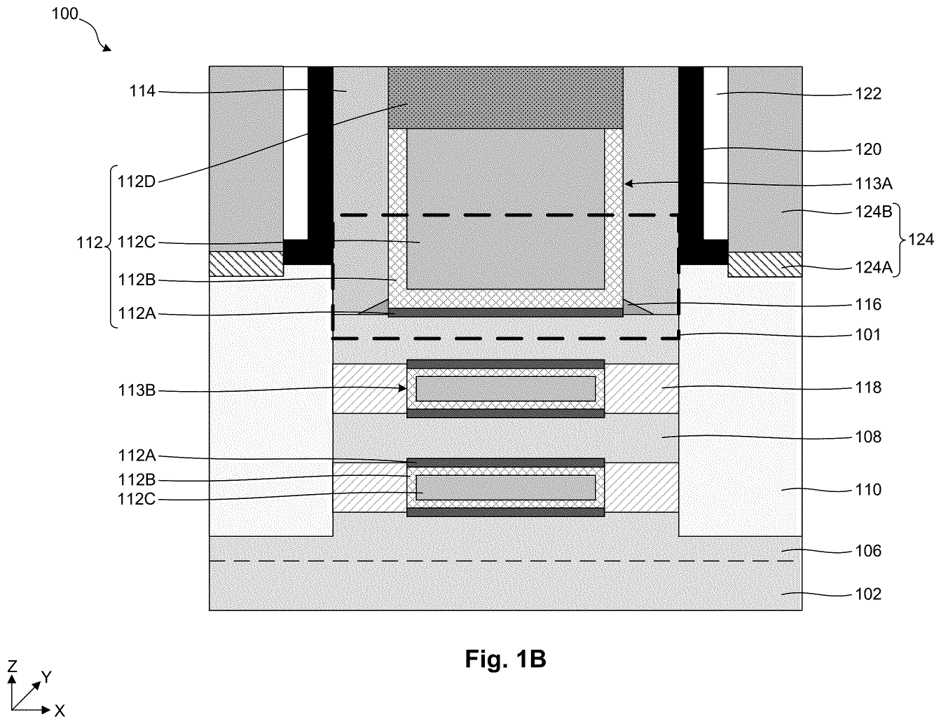

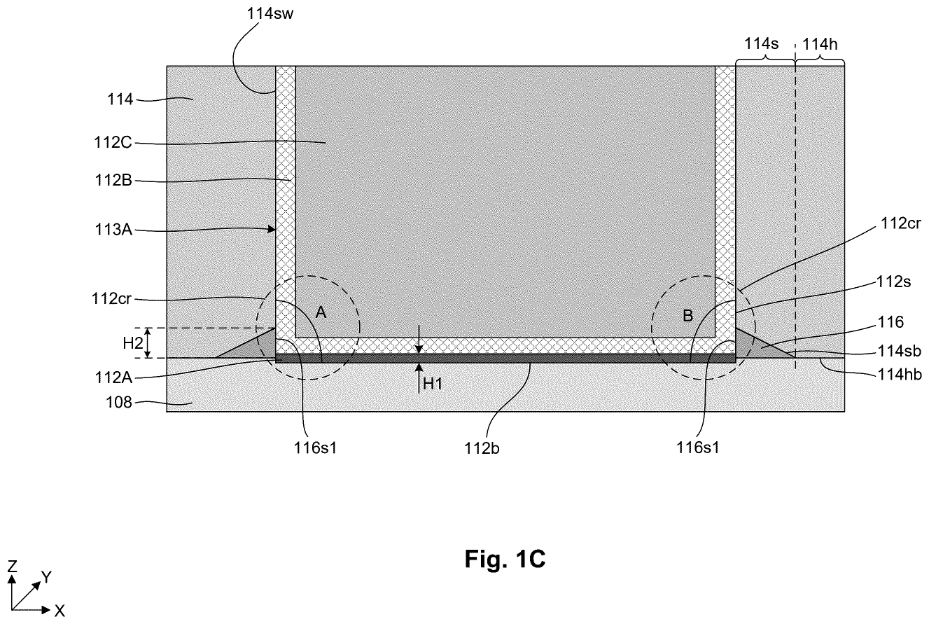

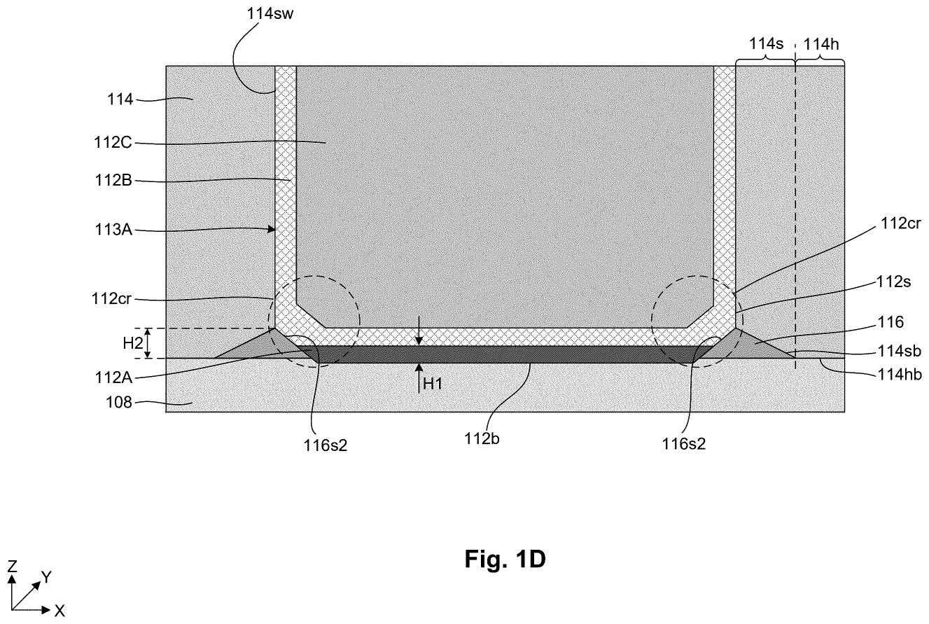

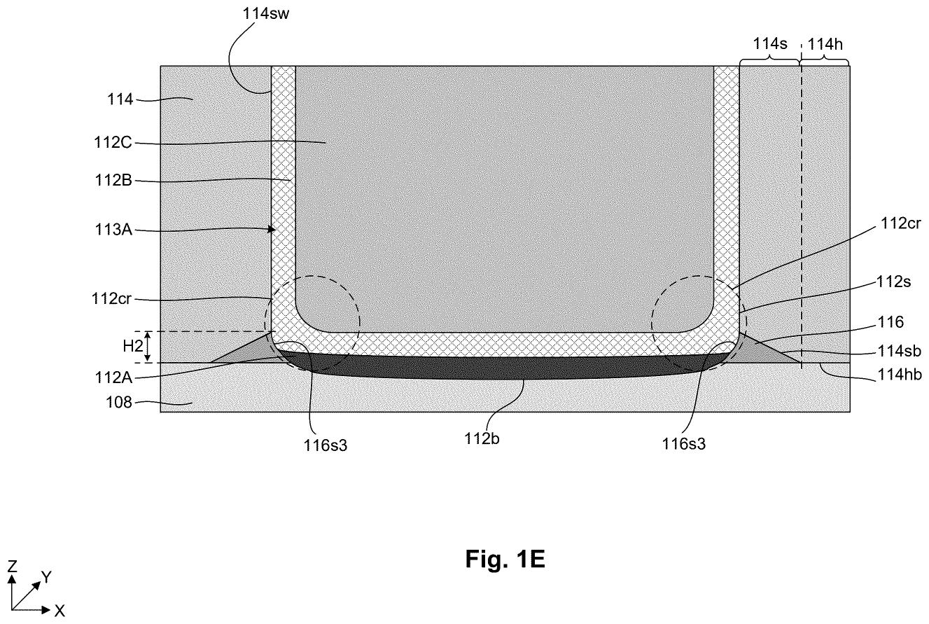

FIG. 1A illustrates an isometric view of a semiconductor device 100, which can represent a GAA FET 100, according to some embodiments. FIG. 1B illustrates a cross-sectional view of GAA FET 100, along line A-A of FIG. 1A, with additional structures that are not shown in FIG. 1A for simplicity, according to some embodiments. FIGS. 1C-1E illustrate different enlarged cross-sectional views of a region 101 of FIG. 1B with additional details that are not shown in FIG. 1B for simplicity, according to some embodiments. The discussion of elements in FIGS. 1A-1E with the same annotations applies to each other, unless mentioned otherwise.

Referring to FIGS. 1A-1E, in some embodiments, GAA FET 100 can include (i) a substrate 102, (ii) shallow trench isolation (STI) regions 104 disposed on substrate 102, (iii) fin-shaped base structures 106 (also referred to as a “sheet base 106” or a “fin base 106”) disposed on substrate 102, (iv) nanostructured channel regions 108 disposed on base structure 106, (v) S/D regions 110 disposed adjacent to nanostructured channel regions 108, (vi) gate structures 112 surrounding nanostructured channel regions 108, (vii) outer gate spacers 114, (viii) interfacial spacer layers 116, (ix) inner gate spacers 118, (x) etch stop layers (ESLs) 120 disposed directly on S/D regions 110, (xi) interlayer dielectric (ILD) layers 122 disposed directly on ESLs 120, and (xii) contact structures 124 disposed on S/D regions 110.

In some embodiments, substrate 102 can be a semiconductor material, such as silicon (Si), germanium (Ge), silicon germanium (SiGe), a silicon-on-insulator (SOI) structure, and a combination thereof. Further, substrate 102 can be doped with p-type dopants (e.g., boron, indium, aluminum, or gallium) or n-type dopants (e.g., phosphorus or arsenic). In some embodiments, STI regions 104 can include an insulating material, such as silicon oxide (SiO₂), silicon nitride (SIN), silicon oxynitride (SiON), silicon oxycarbide (SiOC), silicon carbon nitride (SiCN), silicon oxycarbon nitride (SiOCN), and silicon germanium oxide (SiGeOₓ). In some embodiments, base structures 106 can include a material similar to substrate 102. Base structures 106 can have elongated sides extending along an X-axis.

In some embodiments, nanostructured channel regions 108 can be in the form of nanosheets, nanowires, nanorods, nanotubes, or other suitable nanostructured shapes. As used herein, the term “nanostructured” defines a structure, layer, and/or region as having a horizontal dimension (e.g., along an X-and/or Y-axis) and/or a vertical dimension (e.g., along a Z-axis) less than about 100 nm, for example about 90 nm, about 50 nm, about 10 nm, or other values less than about 100 nm. Nanostructured channel regions 108 can include semiconductor materials similar to or different from substrate 102. In some embodiments, nanostructured channel regions 108 can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. In some embodiments, each of nanostructured channel regions 108 can have a thickness of about 3 nm to about 15 nm along a Z-axis. Though two nanostructured channel regions 108 are shown under gate structure 112, GAA FET 100 can have any number of nanostructured channel regions 108. Though rectangular cross-sections of nanostructured channel regions 108 are shown, nanostructured channel regions 108 can have cross-sections of other geometric shapes (e.g., circular, elliptical, triangular, or polygonal).

In some embodiments, S/D regions 110 can include an epitaxially-grown semiconductor material, such as Si, and n-type dopants, such as phosphorus and other suitable n-type dopants for n-type GAA FET 100. S/D regions 110 can include an epitaxially-grown semiconductor material, such as Si and SiGe, and p-type dopants, such as boron and other suitable p-type dopants for p-type GAA FET 100. Each of S/D regions 110 may refer to a source or a drain, individually or collectively dependent upon the context.

In some embodiments, each gate structure 112 can have an outer gate portion 113A and inner gate portions 113B. In some embodiments, outer gate portions 113A can be disposed on and in physical contact with topmost nanostructured channel regions 108. In some embodiments, inner gate portions 113B can be disposed between adjacent nanostructured channel regions 108 and between adjacent inner gate spacers 118.

Each gate structure can be multi-layered structures and can include (i) an interfacial oxide (IL) layer 112A, (ii) a high-k (HK) gate dielectric layer 112B, (iii) a conductive layer 112C, and (iv) a gate capping layer 112D. In some embodiments, IL layer 112A can be disposed directly on topmost nanostructured channel regions 108. In some embodiments, IL layer 112A can include SiO₂, SiGeOₓ, or germanium oxide (GeOₓ) and can have a thickness H1 of about 0.5 nm to about 1 nm. In some embodiments, HK gate dielectric layer 112B can be disposed directly on IL layer 112A and can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, the sidewalls of HK gate dielectric layer 112B can be in contact with sidewalls of outer gate spacers 114.

In some embodiments, conductive layer 112C can be disposed on HK gate dielectric layer 112B and can be multi-layered structures. The different layers of conductive layer 112C are not shown for simplicity. In some embodiments, conductive layer 112C can include a work function metal (WFM) layer disposed on HK gate dielectric layer 112B and a gate metal fill layer disposed on the WFM layer. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti-Au) alloy, titanium copper (Ti-Cu) alloy, tantalum nitride (TaN), tantalum silicon nitride (TaSiN), tantalum gold (Ta-Au) alloy, and tantalum copper (Ta-Cu). In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials. In some embodiments, the gate metal fill layer can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

In some embodiments, gate capping layer 112D can be disposed directly on HK gate dielectric layer 112B and conductive layer 112C. Gate capping layer 112D can protect the underlying layers from structural and/or compositional degradation during subsequent processing of GAA FET 100. In some embodiments, gate capping layer 112D can include a nitride material, such as SiN, and can have a thickness of about 5 nm to about 10 nm for adequate protection of the underlying layers.

Outer gate spacers 114 can electrically isolate outer gate portions 113A from adjacent S/D regions 110 and from adjacent contact structures 124. In some embodiments, each outer gate spacer 114 can include a horizontal spacer portion 114h and a sloped spacer portion 114s. Horizontal spacer portion 114h can have a bottom surface 114hb with a substantially linear profile and in direct contact with a top surface of the topmost nanostructured channel region 108. Sloped spacer portion 114s can have a bottom surface 114sb with a sloped profile and in direct contact with interfacial spacer layer 116. The interfaces between sloped spacer portions 114s and interfacial spacer layers 116 can have sloped profiles. In some embodiments, outer gate spacers 114 can include an undoped dielectric layer, such as an undoped SiO₂ layer, an undoped SiN layer, an undoped SiON layer, an undoped SiOC layer, an undoped SiCN layer, an undoped SiOCN layer, and any other suitable undoped dielectric layer.

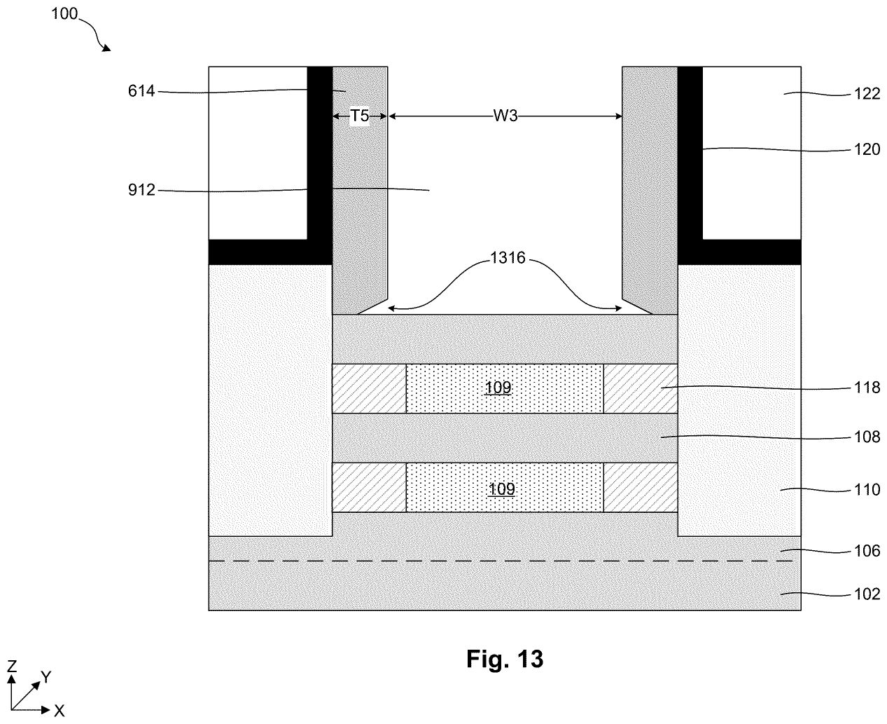

In some embodiments, each interfacial spacer layer 116 can include a dielectric material, such as SiO₂, SIN, SION, SiCN, and SiOCN. In some embodiments, each interfacial spacer layer 116 can include an oxide layer (e.g., SiO₂) of a semiconductor element (e.g., Si) in outer gate spacer 114 and/or in nanostructured channel region 108. Interfacial spacer layers 116 can be disposed between sloped spacer portions 114s and the topmost nanostructured channel regions 108. Such placement of interfacial spacer layers 116 fills interfacial gaps 1316 (not shown in FIGS. 1A-1E, shown in FIG. 13) that are formed between sloped spacer portions 114s and the topmost nanostructured channel regions 108 during the formation of gate structures 112, as explained in detail below. As a result, bottom corner regions 112cr of outer gate portions 113A can be prevented from extending into interfacial gaps 1316 and from being formed under outer gate spacers 114 during the formation of gate structures 112. Preventing outer gate portions 113A from extending under outer gate spacers 114 can increase the spacing between outer gate portions 113A and adjacent S/D regions 110, prevent current leakage or minimize the probability of current leakage between outer gate portions 113A and adjacent S/D regions 110, and improve device performance. Thus, with the use of interfacial spacer layers 116, the bottom corner profiles of outer gate portions 113A can be controlled. Depending on the sidewall profiles of interfacial spacer layers 116, outer gate portions 113A can have a U-shaped cross-sectional profiles with different bottom corner profiles, as discussed below with reference to Figs. IC, 1D, and 1E.

Referring to FIG. 1C, in some embodiments, each interfacial spacer layer 116 on either side of outer gate portion 113A can have (i) a triangular cross-sectional profile, (ii) a substantially vertical sidewall 116sl with a height H2 of about 2 nm to about 5 nm facing and in contact with outer gate portion 113A, (iii) sidewall 116sl substantially aligned with sidewall 114sw of outer gate spacer 114, (iv) a sloped sidewall facing and in contact with outer gate spacer 114, (v) a substantially right-angled corner (e.g., about 85 degrees to about 90 degrees) between sidewall 116s1 and a bottom surface of interfacial spacer layer 116, and (vi) an acute-angled corner (e.g., about 35 degrees to about 75 degrees) between the sloped sidewall and bottom surface of interfacial spacer layer 116.

In some embodiments, due to such structural profiles of interfacial spacer layers 116 on either side of outer gate portion 113A in FIG. 1C, (i) outer gate portion 113A can be formed with a U-shaped cross-sectional profile, (ii) bottom corner regions 112cr can be formed with substantially right-angled corner profiles (e.g., about 90 degrees to about 95 degrees), (iii) sidewalls 112s of outer gate portion 113A can form angles A and B of about 90 degrees to about 95 degrees with a bottom surface 112b of outer gate portion 113A, (iv) sidewalls of IL layer 112A can form angles of about 90 degrees to about 95 degrees with a bottom surface of IL layer 112A, (v) sidewalls of HK gate dielectric layer 112B can form angles of about 90 degrees to about 95 degrees with a bottom surface of HK gate dielectric layer 112B, and (vi) sidewalls of conductive layer 112C can form angles of about 90 degrees to about 95 degrees with a bottom surface of conductive layer 112A.

In some embodiments, the ratio between dimensions H1 and H2 can be about 0.1 to about 0.5. In some embodiments, the interfaces between interfacial spacer layers 116 and IL layer 112A and between interfacial spacer layers 116 and HK gate dielectric layer 112B can have linear profiles. The above discussed structural profiles and dimensions of interfacial spacer layers 116 and outer gate portions 113A in FIG. 1C can prevent current leakage or minimize the probability of current leakage between outer gate portions 113A and adjacent S/D regions 110, thus improving device performance.

In some embodiments, interfacial spacer layers 116 can have structural profiles as shown in FIG. 1D, instead of the structural profiles shown in FIG. 1C. Referring to FIG. 1D, in some embodiments, each interfacial spacer layer 116 on either side of outer gate portion 113A can have (i) a triangular cross-sectional profile, (ii) a first sloped sidewall 116s2 facing and in contact with outer gate portion 113A, (iii) a second sloped sidewall facing and in contact with outer gate spacer 114, and (iv) an acute-angled corner (e.g., about 45 degrees to about 85 degrees) between sidewall 116s2 and bottom surface of interfacial spacer layer 116. In some embodiments, due to such structural profiles of interfacial spacer layers 116 on either side of outer gate portion 113A in FIG. 1D, (i) outer gate portion 113A can be formed with a U-shaped cross-sectional profile, (ii) bottom corner regions 112cr can be formed with beveled corner profiles, (iii) sidewalls of IL layer 112A can be formed with sloped profiles, (iv) bottom corners of HK gate dielectric layer 112B can be formed with beveled corner profiles, and (v) bottom corners of conductive layer 112C can be formed with beveled corner profiles. In some embodiments, the interfaces between interfacial spacer layers 116 and IL layer 112A and between interfacial spacer layers 116 and HK gate dielectric layer 112B can have sloped profiles. The above discussed structural profiles and dimensions of interfacial spacer layers 116 and outer gate portions 113A in FIG. 1D can prevent current leakage or minimize the probability of current leakage between outer gate portions 113A and adjacent S/D regions 110, thus improving device performance.

In some embodiments, interfacial spacer layers 116 can have structural profiles as shown in FIG. 1E, instead of the structural profiles shown in FIGS. 1C or 1D. Referring to FIG. 1E, in some embodiments, each interfacial spacer layer 116 on either side of outer gate portion 113A can have (i) a triangular cross-sectional profile, (ii) a curved sidewall 116s3 facing and in contact with outer gate portion 113A, (iii) a sloped sidewall facing and in contact with outer gate spacer 114, and (iv) an acute-angled corner (e.g., about 35 degrees to about 75 degrees) between the sloped sidewall and bottom surface of interfacial spacer layer 116. In some embodiments, due to such structural profiles of interfacial spacer layers 116 on either side of outer gate portion 113A in FIG. 1E, (i) outer gate portion 113A can be formed with a U-shaped cross-sectional profile, (ii) bottom corner regions 112cr can be formed with rounded corner profiles, (iii) sidewalls of IL layer 112A can be formed with curved profiles, (iv) bottom corners of HK gate dielectric layer 112B can be formed with rounded corner profiles, and (v) bottom corners of conductive layer 112C can be formed with rounded corner profiles. In some embodiments, the interfaces between interfacial spacer layers 116 and IL layer 112A and between interfacial spacer layers 116 and HK gate dielectric layer 112B can have curved profiles. The above discussed structural profiles and dimensions of interfacial spacer layers 116 and outer gate portions 113A in FIG. 1E can prevent current leakage or minimize the probability of current leakage between outer gate portions 113A and adjacent S/D regions 110, thus improving device performance.

Referring to FIGS. 1A and 1B, inner gate spacers 118 can electrically isolate inner gate portions 113B from adjacent S/D regions 110. In some embodiments, each inner gate spacer 118 can have a height of about 3 nm to about 20 nm and a thickness of about 1 nm to about 10 nm. Within these ranges of height and thickness, inner gate spacers 118 can adequately electrically isolate inner gate portions 113B from adjacent S/D regions 110 without compromising the device size and manufacturing cost.

In some embodiments, ESLs 120 can be disposed directly on S/D regions 110. In some embodiments, ESLs 120 can have a dielectric constant of about 4 to about 7 and can include a dielectric material, such as lanthanum oxide (LaO), aluminum oxide (Al₂O₃), yttrium oxide (Y₂O₃), tantalum carbon nitride (TaCN), zirconium silicide (ZrSi), SiOCN, SiOC, SiCN, zirconium nitride (ZrN), zirconium aluminum oxide (ZrAlO), TiO₂, Ta₂O₃, ZrO₂, HfO₂, SiN, hafnium silicide (HfSi), aluminum oxynitride (AlON), SiO₂, SiC, SiN, and zinc oxide (ZnO). In some embodiments, ILD layers 122 can be disposed directly on ESLs 120. In some embodiments, ILD layers 122 can include an insulating material, such as SiO₂, SiN, SiON, SiCN, and SiOCN.

In some embodiments, each contact structure 124 can include (i) a silicide layer 124A, and (ii) contact plugs 124B disposed on silicide layer 124A. In some embodiments, silicide layer 124A in n-type GAA FET 100 can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), curopium silicide (EuₓSi_{y}), thorium silicide (ThₓSi_{y}), other suitable metal silicide materials, or a combination thereof. In some embodiments, silicide layer 124A in p-type GAA FET 100 can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof. In some embodiments, contact plug 124B can include conductive materials, such as Co, W, Ru, Al, Mo, Ir, Ni, Osmium (Os), rhodium (Rh), other suitable conductive materials, and a combination thereof.

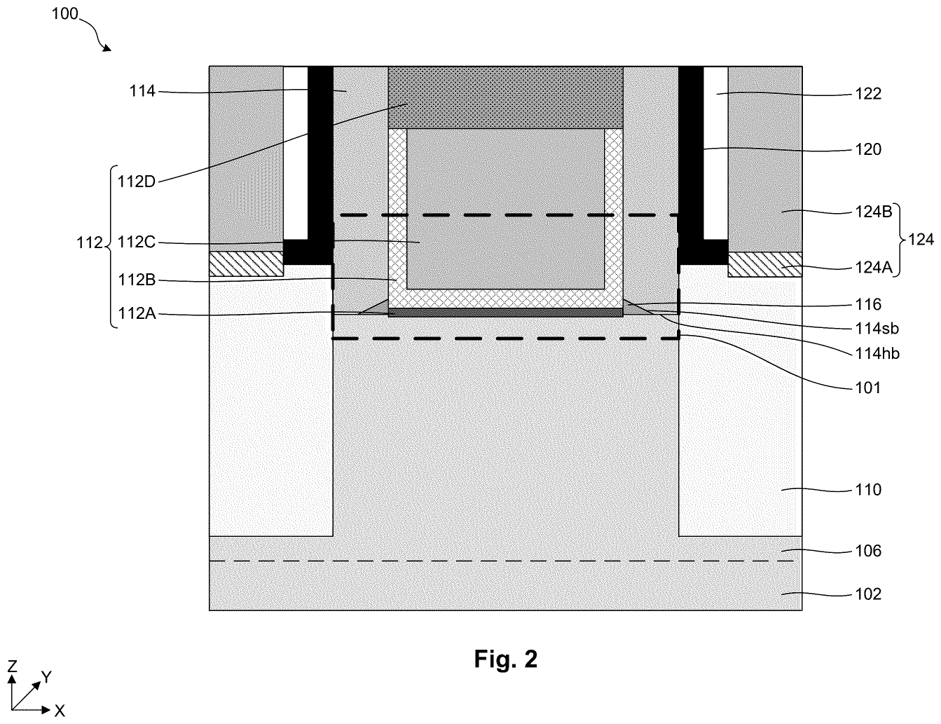

In some embodiments, semiconductor device 100 can represent a FinFET 100, instead of GAA FET 100 and can have a cross-sectional view of FIG. 2 across line A-A of FIG. 1A. The discussion of elements in FIGS. 1A-1E and 2 with the same annotations applies to each other, unless mentioned otherwise. The discussion of outer gate portion 113A of GAA FET 100 in FIGS. 1B-1E applies to gate structure 112 of FinFET 100 in FIG. 2, unless mentioned otherwise. Referring to FIG. 2, unlike GAA FET 100, FinFET 100 can have (i) fin structures 106 instead of nanostructured channel regions 108 and base structures 106, (ii) gate structures 112 disposed directly on base structures 106, (iii) fin regions of fin structures 106 underlying gate structures 112 and adjacent to S/D regions 110 function as channel regions, (iv) horizontal spacer portions 114h of outer gate spacers 114 disposed directly on fin structures 106, and (v) interfacial spacer layers 116 disposed directly on fin regions of fin structures 106 underlying outer gate spacers 114.

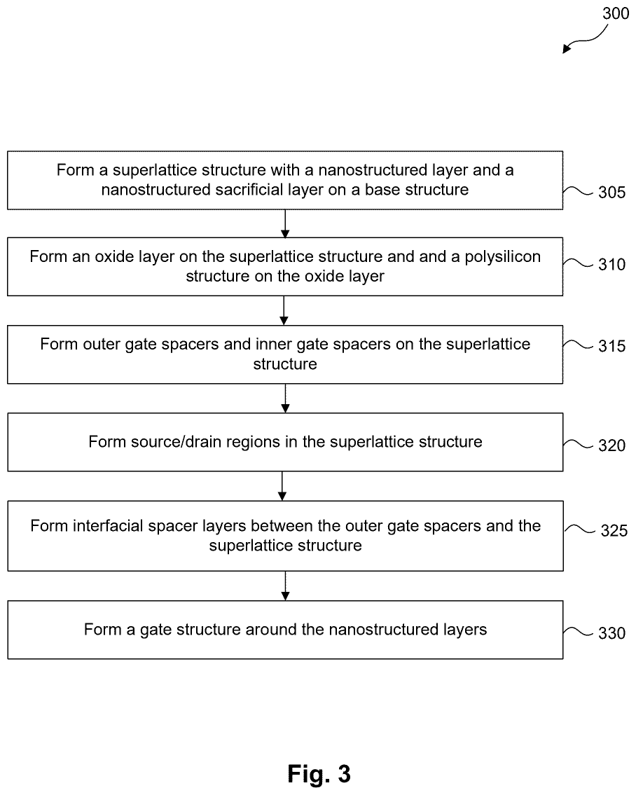

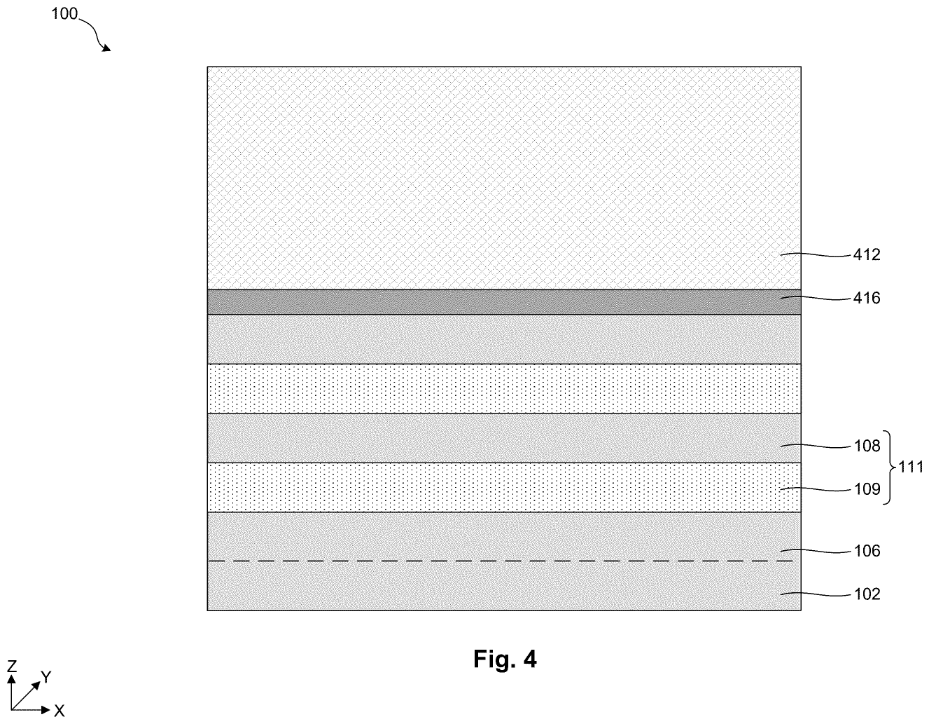

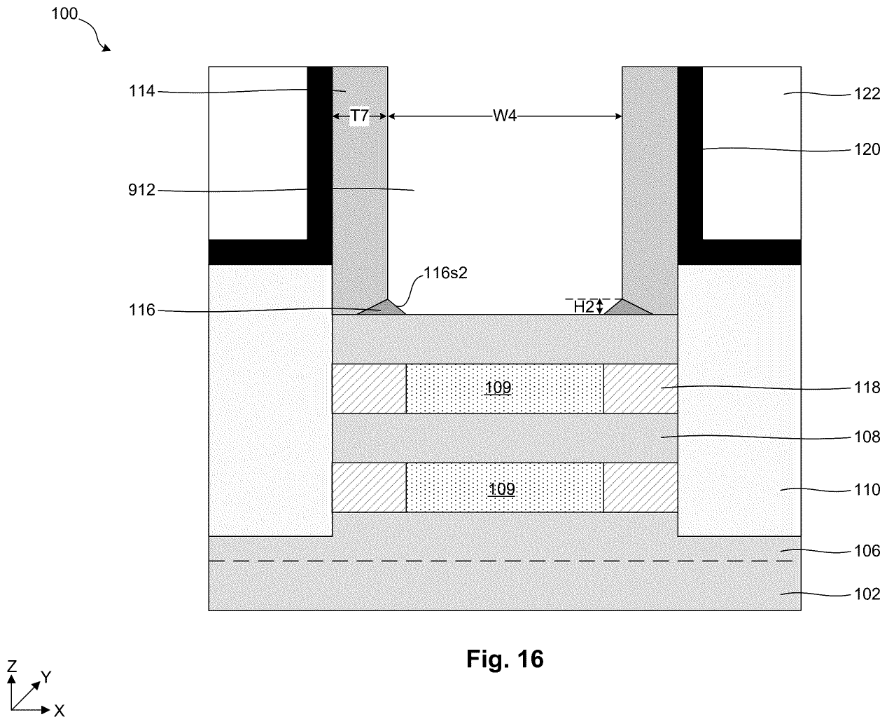

FIG. 3 is a flow diagram of an example method 300 for fabricating GAA FET 100 with the cross-sectional views of FIGS. 1B-1E, according to some embodiments. For illustrative purposes, the operations illustrated in FIG. 3 will be described with reference to the example fabrication process for fabricating GAA FET 100 as illustrated in FIGS. 4-20. FIGS. 4-20 are cross-sectional views of GAA FET 100 along line A-A of FIG. 1A at various stages of fabrication of GAA FET 100, according to some embodiments. Operations can be performed in a different order or not performed depending on specific applications. It should be noted that method 300 may not produce a complete GAA FET 100. Accordingly, it is understood that additional processes can be provided before, during, and after method 300, and that some other processes may only be briefly described herein. The discussion of elements in FIGS. 1A-1E, 2, and 11-16 with the same annotations applies to each other, unless mentioned otherwise.

Referring to FIG. 3, in operation 305, a superlattice structure with a nanostructured layer and a nanostructured sacrificial layer is formed on a base structure. For example, as shown in FIG. 4, a superlattice structure 111 (also referred to as “a nanosheet stack 111”) is formed on fin-shaped base structure 106, which is formed on substrate 102. Superlattice structure 111 can include nanostructured layers 108 and nanostructured sacrificial layers 109 arranged in an alternating configuration. In some embodiments, nanostructured layers 108 can include Si, and nanostructured sacrificial layers 109 can include SiGe.

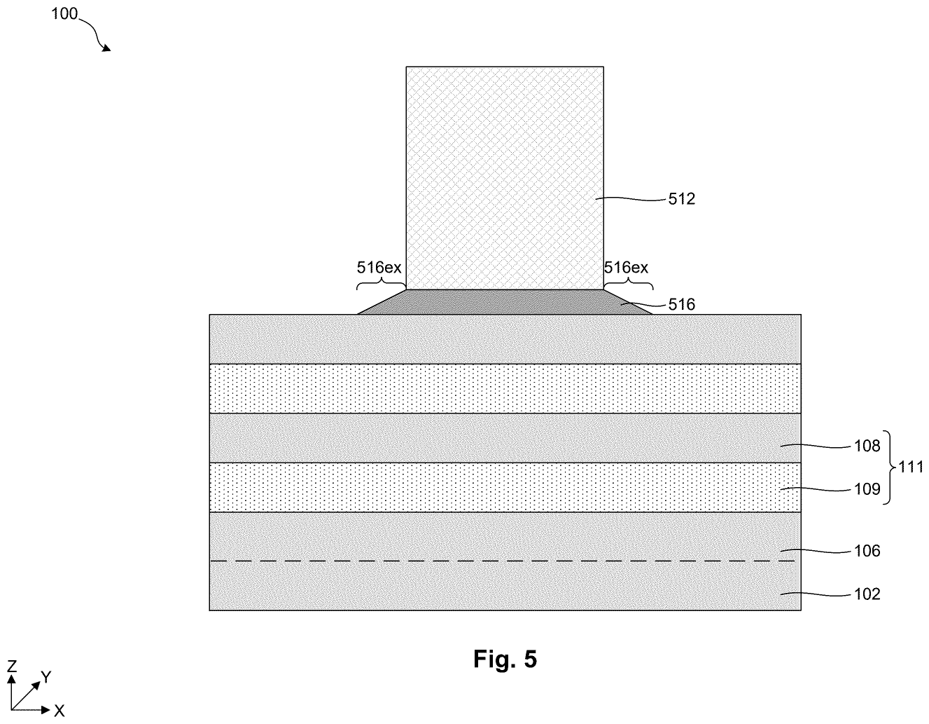

Referring to FIG. 3, in operation 310, an oxide layer is formed on the superlattice structure, and a polysilicon structure is formed on the oxide layer. For example, as described with reference to FIGS. 4 and 5, an oxide layer 516 is formed on the topmost nanostructured layer 108 of superlattice structure 111 and a polysilicon structure 512 is formed on oxide layer 516. In some embodiments, the formation of oxide layer 516 can include (i) performing an oxidation process on superlattice structure 111 to form a thermal oxide layer 416, as shown in FIG. 4, and (ii) performing an etching process on thermal oxide layer 416 after the formation of polysilicon structure 512 to form oxide layer 516, as shown in FIG. 5. In such embodiments, oxide layer 516 can include an oxide (e.g., SiO₂) of the material (e.g., Si) of the topmost nanostructured layer 108 of superlattice structure 111. In some embodiments, the formation of oxide layer 516 can include (i) exposing the topmost nanostructured layer 108 of superlattice structure 111 to a precursor, such as tetraethylorthosilicate (TEOS) in a chemical vapor deposition (CVD) process at a temperature of about 650° C. to about 750° C. to deposit a chemical oxide layer 416 (e.g., SiO₂), as shown in FIG. 4, and (ii) performing an etching process on chemical oxide layer 416 after the formation of polysilicon structure 512 to form oxide layer 516, as shown in FIG. 5.

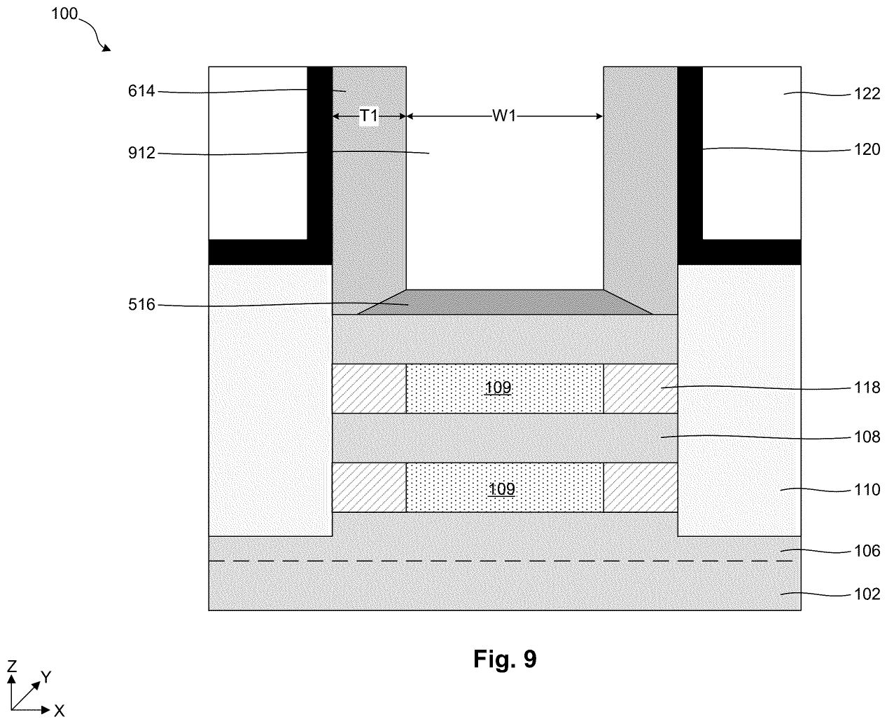

In some embodiments, the formation of polysilicon structure 512 can include sequential operations of (i) depositing an amorphous, polycrystalline, or monocrystalline polysilicon layer 412 on thermal or chemical oxide layer 416, as shown in FIG. 4, and (ii) performing a patterning process (e.g., lithography process) and an etching process on polysilicon layer 412 to form polysilicon structure 512, as shown in FIG. 5. In some embodiments, the same etching process can be used to etch oxide layer 416 and polysilicon layer 412. As a result, oxide layer 516 can be formed with sloped sidewalls and extended oxide regions 516ex, which laterally extend over sidewalls of polysilicon structure 512 due to the difference in the etching selectivity between the materials of oxide layer 416 and polysilicon layer 412. These extended oxide regions 516ex can lead to the formation of interfacial gaps between outer gate spacers 114 and the topmost nanostructured layer 108 during the replacement of polysilicon structure 512 and oxide layer 516 with gate structure 112. To avoid gate structure 112 from extending into these interfacial gaps and from being formed under outer gate spacers 114, which can lead to current leakage between gate structure 112 and S/D region 110, the interfacial gaps are filled with interfacial spacer layers 116, as discussed below with reference to FIGS. 9-17.

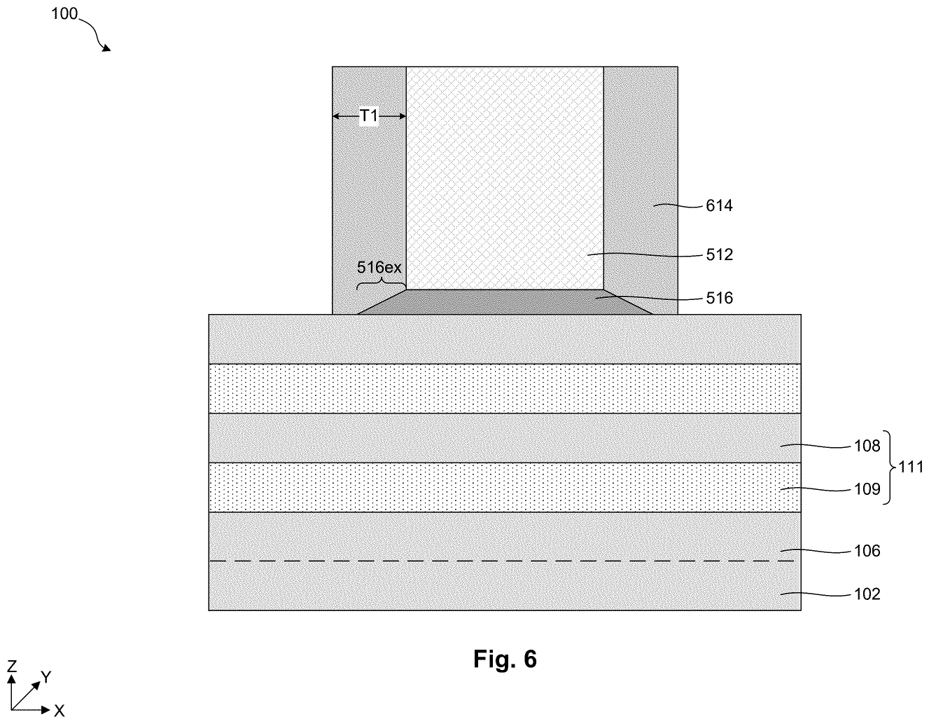

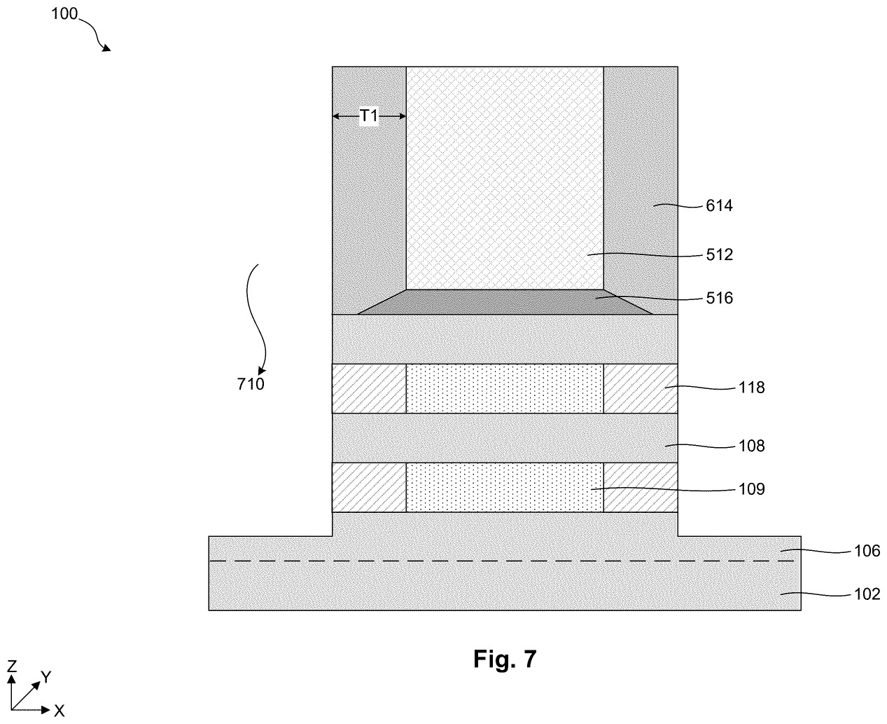

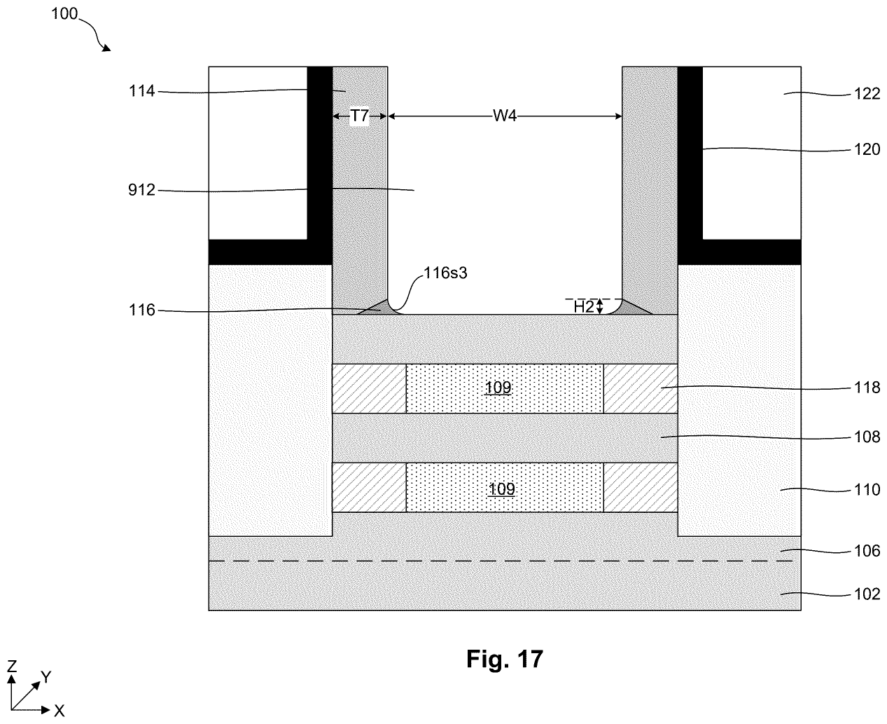

Referring to FIG. 3, in operation 315, outer gate spacers and inner gate spacers are formed on the superlattice structure. For example, as described with reference to FIGS. 6 and 7, outer gate spacers 614 and inner gate spacers 118 are formed on superlattice structure 111. In some embodiments, the formation of outer gate spacers 614 can include sequential operations of (i) depositing a dielectric material layer (not shown) on the structure of FIG. 5, (ii) performing an anneal process to densify the dielectric material layer, and (iii) etching horizontal portions of the densified dielectric material layer on superlattice structure 111 to form outer gate spacers 614 with a thickness T1, as shown in FIG. 6. In subsequent operations, outer gate spacers 614 is thinned down to a thickness of T7 to form outer gate spacers 114, as shown in FIG. 17.

The formation of inner gate spacers 118 can include sequential operations of (i) performing an etching process on the structure of FIG. 6 to etch the portions of superlattice structure 111 not covered by polysilicon structure 512 and outer gate spacers 614 and form openings 710, as shown in FIG. 7, (ii) performing an etching process on sidewalls of nanostructured sacrificial layers 109 facing openings 710 to form inner gate spacer openings (not shown), (iii) depositing a dielectric material layer (not shown) to fill the inner gate spacer openings, on sidewalls of outer gate spacers 614 and nanostructured layers 108, and on top surfaces of polysilicon structure 512, outer gate spacers 614, and base structure 106, and (iv) performing an etching process on the dielectric material layer to form the structure of FIG. 7.

In some embodiments, the etching of superlattice structure 111 to form openings 710 can include a plasma-based dry etching process using etching gases, such as carbon tetrafluoride (CF₄), sulfur dioxide (SO₂), hexafluoroethane (C₂F₆), chlorine (Cl₂), nitrogen trifluoride (NF₃), sulfur hexafluoride (SF₆), and hydrogen bromide (HBr), with mixture gases, such as hydrogen (H₂), oxygen (O₂), nitrogen (N₂), and argon (Ar). The etching can be performed at a temperature of about 25° C. to about 200° C. under a pressure from about 5 mTorr to about 50 mTorr. The flow rate of the etching gases can be about 5 standard cubic centimeters per minute (sccm) to about 100 sccm. The plasma power can be about 50 W to about 200 W with a bias voltage from about 30 V to about 200 V.

In some embodiments, the etching of the sidewalls of nanostructured sacrificial layers 109 can include a dry etching process that has a higher etch selectivity for SiGe of nanostructured sacrificial layers 109 than Si of nanostructured layers 108. For example, halogen-based chemistries can exhibit etch selectivity that is higher for Ge than for Si. Therefore, halogen gases can etch SiGe faster than Si. In some embodiments, the halogen-based chemistries can include fluorine-based and/or chlorine-based gasses. Alternatively, the etching of nanostructured sacrificial layers 109 can include a wet etching process with a higher selectivity for SiGe than Si. For example, the wet etching process can include using a mixture of sulfuric acid (H₂SO₄) and hydrogen peroxide (H₂O₂) and/or a mixture of ammonia hydroxide (NH₄OH) with H₂O₂ and deionized (DI) water.

In some embodiments, the etching of the dielectric material layer to form inner gate spacers 118 can include an anisotropic dry etching process and can have a higher etching rate along a Z-axis than along an X-axis or a Y-axis. As a result, the portions of the dielectric material layer on sidewalls of outer gate spacers 614 and nanostructured layers 108 and on top surfaces of polysilicon structure 512, outer gate spacers 614, and base structure 106 can be etched without etching the portions of the dielectric material layer in the inner gate spacer openings.

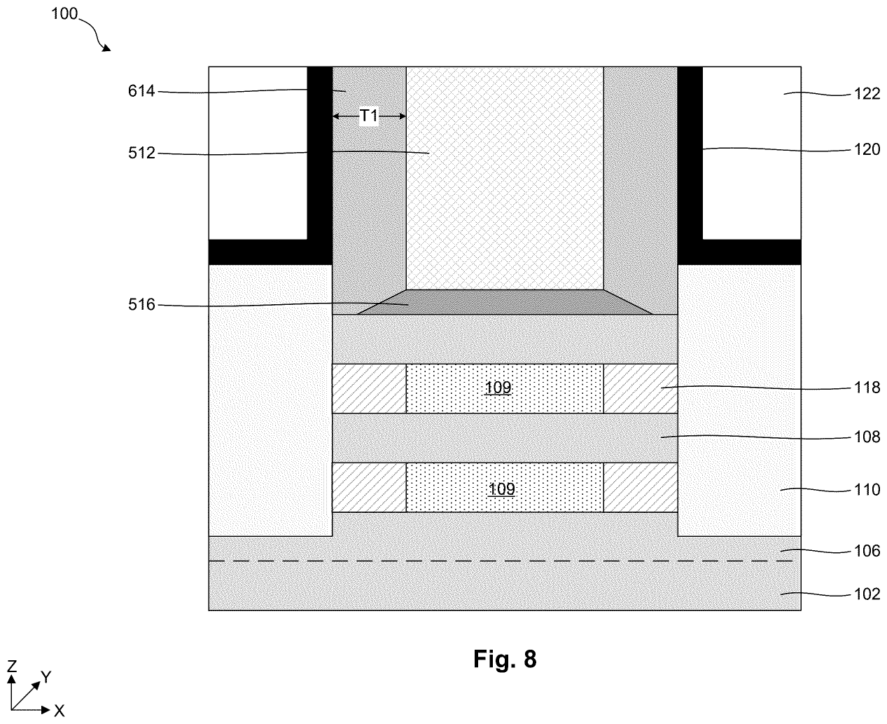

Referring to FIG. 3, in operation 320, S/D regions are formed in the superlattice structure. For example, as shown in FIG. 8, S/D regions 110 are formed in superlattice structure 111. In some embodiments, the formation of S/D regions 110 can include epitaxially growing a semiconductor material (e.g., Si or SiGe) with n-type or p-type dopants in openings 710, as shown in FIG. 8. The formation of S/D regions 110 can be followed by the formation of ESLs 120 and ILD layers 122, as shown in FIG. 8.

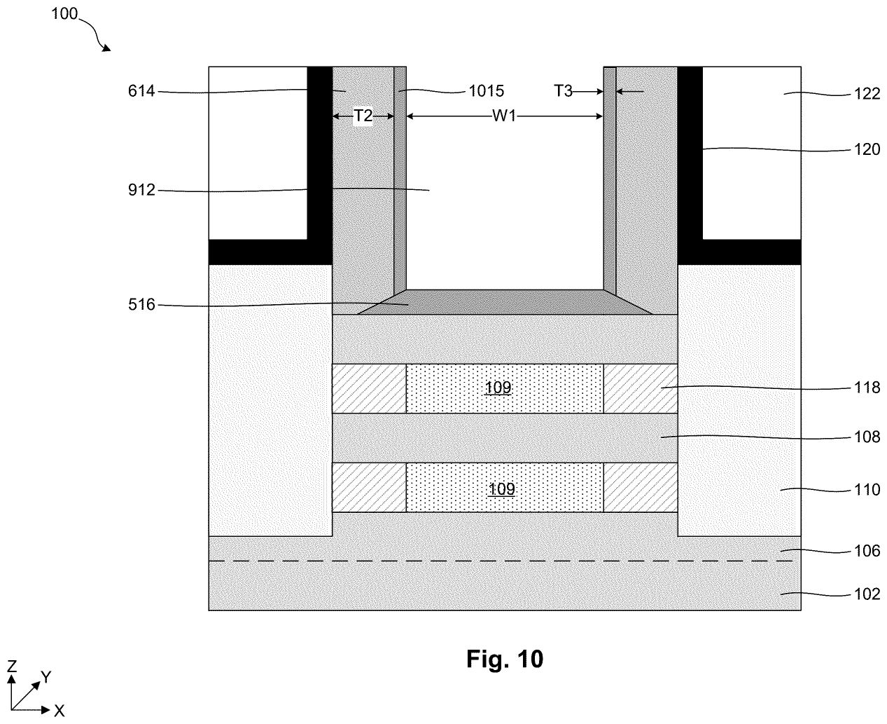

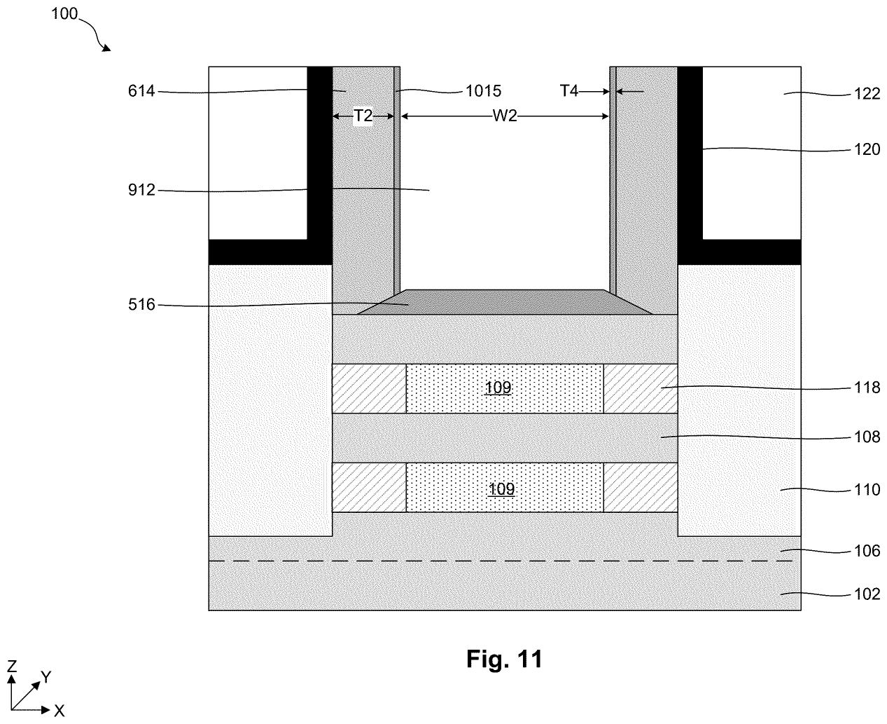

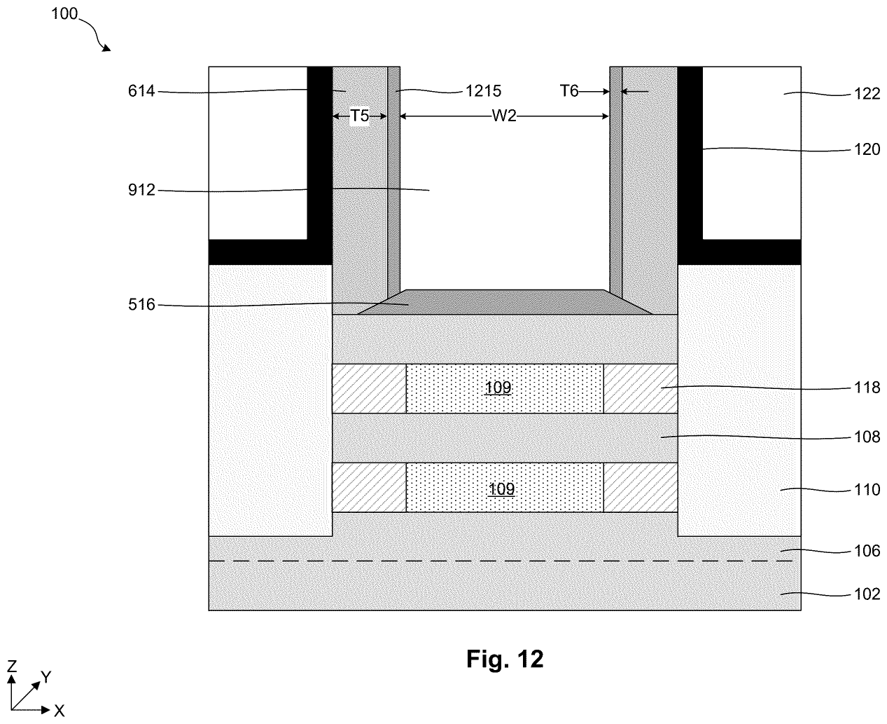

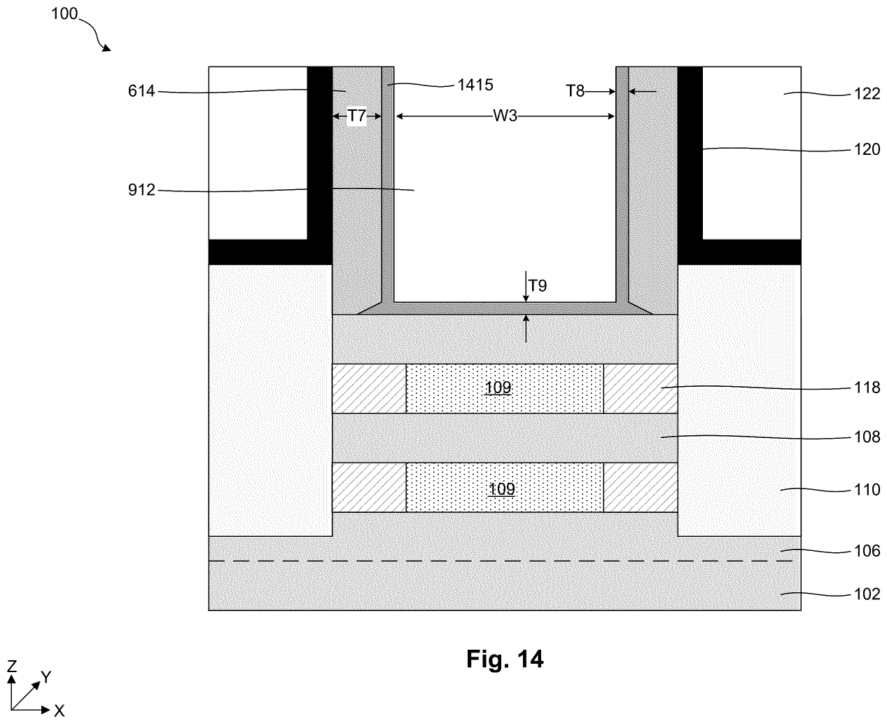

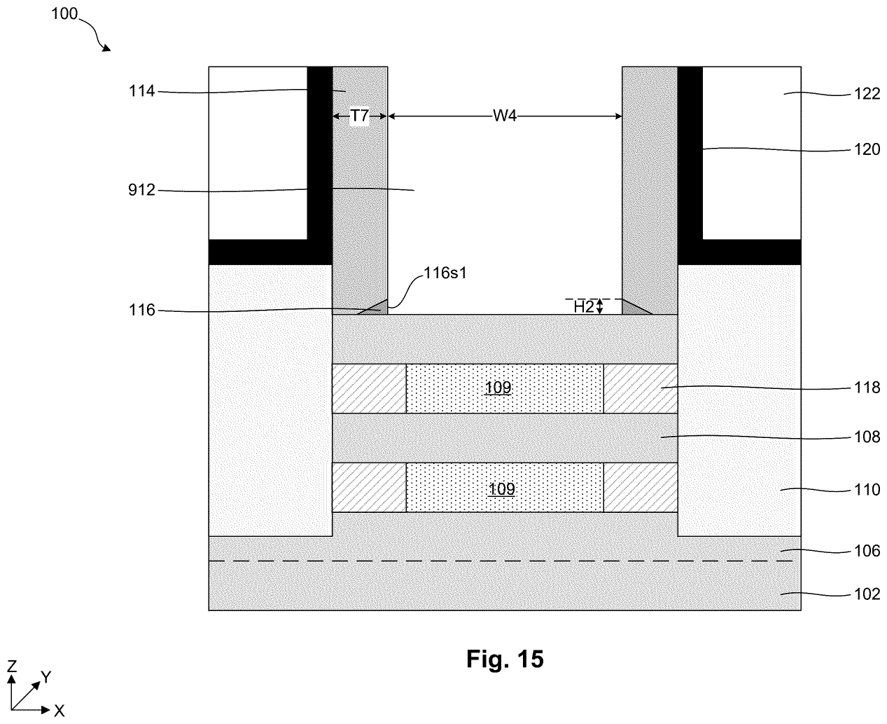

Referring to FIG. 3, in operation 325, interfacial spacer layers are formed between the outer gate spacers and the superlattice structure. For example, as described with reference to FIGS. 9-17, interfacial spacer layers 116 are formed between outer gate spacers 114 and the topmost nanostructured layer 108 of superlattice structure 111. The formation of interfacial spacer layers 116 can include sequential operations of (i) removing polysilicon structure 512 to form a gate opening 912 with a width W1, as shown in FIG. 9, (ii) performing a first oxidation process on outer gate spacers 614 of FIG. 9 to form oxide layer 1015, as shown in FIG. 10, (iii) performing a first oxide etch process on the structure of FIG. 10 to reduce the thickness of oxide layer 1015 from thickness T3 to a thickness T4 and increasing the width of gate opening 912 from width W1 to a width W2, as shown in FIG. 11, (iv) performing a second oxidation process on outer gate spacers 614 of FIG. 11 to further oxidize sidewall portions of outer gate spacers 614 to form oxide layer 1215, as shown in FIG. 12, (v) performing a second oxide etch process on the structure of FIG. 12 to remove oxide layers 516 and 1215, as shown in FIG. 13, (vi) performing a third oxidation process on the structure of FIG. 13 to form oxide layer 1415, as shown in FIG. 14, and (vii) performing a third oxide etch process on the structure of FIG. 14 to etch oxide layer 1415 and form interfacial spacer layers 116 and outer gate spacers 114, as shown in FIG. 15, 16, or 17. In some embodiments, depending on the etching parameters of the third oxide etch process, interfacial spacer layers 116 can be formed with structural profiles of FIG. 15, 16, or 17.

In some embodiments, the first oxidation process can oxidize sidewall portions of outer gate spacers 614 of FIG. 9 to form oxide layer 1015 with a thickness T3 of about 4 nm to about 10 nm, as shown in FIG. 10. In some embodiments, outer gate spacers 614 can include layers of SiOCN, SiOC, or SiON and the first oxidation process can convert the sidewall portions of the layer of SiOCN, SiOC, or SiON into SiO₂ to form oxide layer 1015. As a result of the formation of oxide layer 1015, the thickness of outer gate spacers 614 can be reduced from thickness T1 to a thickness T2, as shown in FIG. 10. In some embodiments, the first oxidation process can include a high temperature plasma oxidation process. The high temperature plasma oxidation process can include exposing outer gate spacers 614 to oxygen radicals in a plasma at a high temperature of about 400° C. to about 900° C. under a chamber pressure of about 0.003 torr to about 3.0 torr. The plasma can be generated in the plasma chamber using a gas mixture of oxygen at a flow rate of about 6000 sccm to about 6500 sccm, nitrogen at a flow rate of about 3800 sccm to about 4000 sccm, and hydrogen at a flow rate of about 160 sccm to about 200 sccm.

In some embodiments, the first oxide etch process can include a wet etch process. The wet etch process can include exposing oxide layer 1015 to a hydrofluoric (HF) acid solution in deionized (DI) water. The volumetric ratio between HF acid and DI water (HF: DI) can be about 1:100 to about 1:500.

In some embodiments, the second oxidation process can further oxidize sidewall portions of outer gate spacers 614 of FIG. 11 to form oxide layer 1215 with a thickness T6 of about 4 nm to about 10 nm, as shown in FIG. 12. In some embodiments, the second oxidation process can be similar to the first oxidation process and can convert the sidewall portions of outer gate spacers 614 having the layers of SiOCN, SiOC, or SiON into SiO₂ to form oxide layer 1215. As a result of the formation of oxide layer 1215, the thickness of outer gate spacers 614 can be reduced from thickness T2 to a thickness T5, as shown in FIG. 12.

In some embodiments, the second oxide etch process can include a dry etch process. The dry etch process can include exposing oxide layers 516 and 1215 to a gas mixture of HF gas and ammonia (NH₃) gas under a chamber pressure of about 0.1 torr to about 1.0 torr. The gas ratio of HF to NH₃ can be about 1:4 to about 1:5. The removal of oxide layer 516 by the second oxide etch process results in the formation of interfacial gaps 1316 between outer gate spacers 614 and the topmost nanostructured layer 108, as shown in FIG. 13. The removal of oxide layer 1215 by the second oxide etch process results in the increase of the width of gate opening 912 from width W2 to a width W3, as shown in FIG. 13.

In some embodiments, the third oxidation process can oxidize sidewalls portions of outer gate spacers 614 that are exposed in gate opening 912 to form vertical portions of oxide layer 1415 with a thickness T8, as shown in FIG. 14. At the same time, the third oxidation process can oxidize the top surface of nanostructured layer 108 that is exposed in gate opening 912 to form a horizontal portion of oxide layer 1415, as shown in FIG. 14. The horizontal portion of oxide layer 1415 extends to fill interfacial gaps 1316 and is formed with a thickness T9, which is greater than thickness T8. In some embodiments, the third oxidation process can be similar to the first oxidation process and can convert the sidewall portions of outer gate spacers 614 having the layers of SiOCN, SiOC, or SiON into SiO₂ to form the vertical portions of oxide layer 1415. In some embodiments, the third oxidation process can also convert a top portion of nanostructured layer 108 having a layer of Si into SiO₂ to form the horizontal portion of oxide layer 1415. As a result of the formation of oxide layer 1415, the thickness of outer gate spacers 614 can be reduced from thickness T5 to a thickness T7, as shown in FIG. 14.

In some embodiments, the third oxide etch process can be similar to the second oxide etch process, except the duration of the third oxide etch process is shorter than the second oxide etch process. The duration of the third oxide etch process is shorter because oxide layer 1415 is partially removed to leave portions of oxide layer 1415 in interfacial gaps 1316, unlike the complete removal of oxide layer 1215 during the second oxide etch process. The removal of the vertical portions of oxide layer 1415 by the third oxide etch process results in the increase of the width of gate opening 912 from width W3 to a width W4, as shown in FIGS. 15, 16, and 17.

In some embodiments, oxide layer 1415 can be formed by depositing a layer of insulating oxide material, such as SiO₂, SION, SiCN, and SiOCN using a CVD process or an atomic layer deposition (ALD) process, instead of performing the third oxidation process. In such embodiments, the thickness of outer gate spacers 614 remains at thickness T5 and is not reduced from thickness T5 to thickness T7. As the thickness of outer gate spacers remains at T5, the width of gate opening 912 remains at width W3 and is not increased from width W3 to width W4 after the third oxide etch process.

As discussed above, the first, second, and third oxidation and oxide etch processes can be used to form interfacial spacer layers 116 and, at the same time, can be used to tune the width of gate opening 912 as desired. Thus, the width of gate opening 912, which defines the gate length of subsequently-formed gate structure 112, may not be limited by the width of polysilicon structure 512.

In some embodiments, the first and second oxidation and oxide etch processes may not be performed and the formation of interfacial spacer layers 116 can include sequential operations of (i) removing polysilicon structure 512 to form a gate opening 912 with a width W1, as shown in FIG. 9, (ii) removing oxide layer 516 using a dry etch process similar to the second oxide etch process to form interfacial oxide gaps 1316, (iii) performing the third oxidation process or the CVD or ALD process on outer gate spacers 614 of FIG. 9 to form oxide layer 1415, as shown in FIG. 14, and (iv) performing the third oxide etch process on the structure of FIG. 14 to etch oxide layer 1415 to form interfacial spacer layers 116 and outer gate spacers 114, as shown in FIG. 15, 16, or 17.

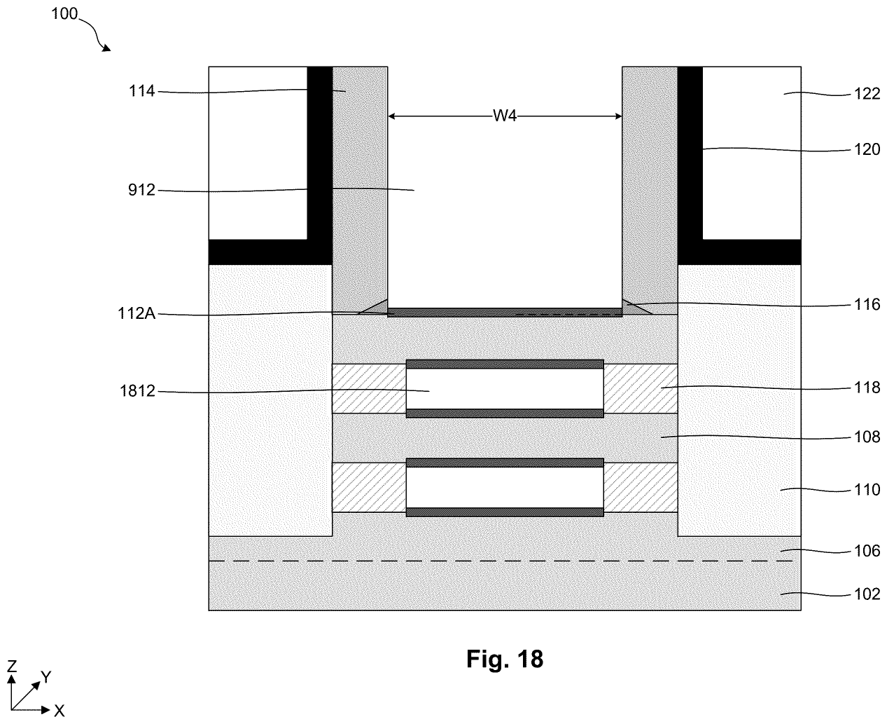

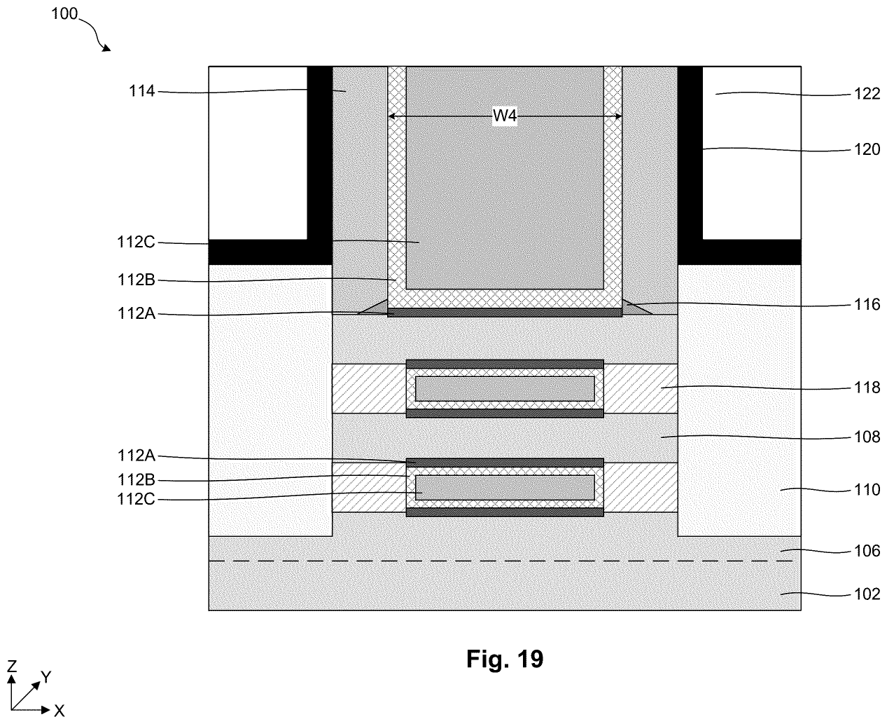

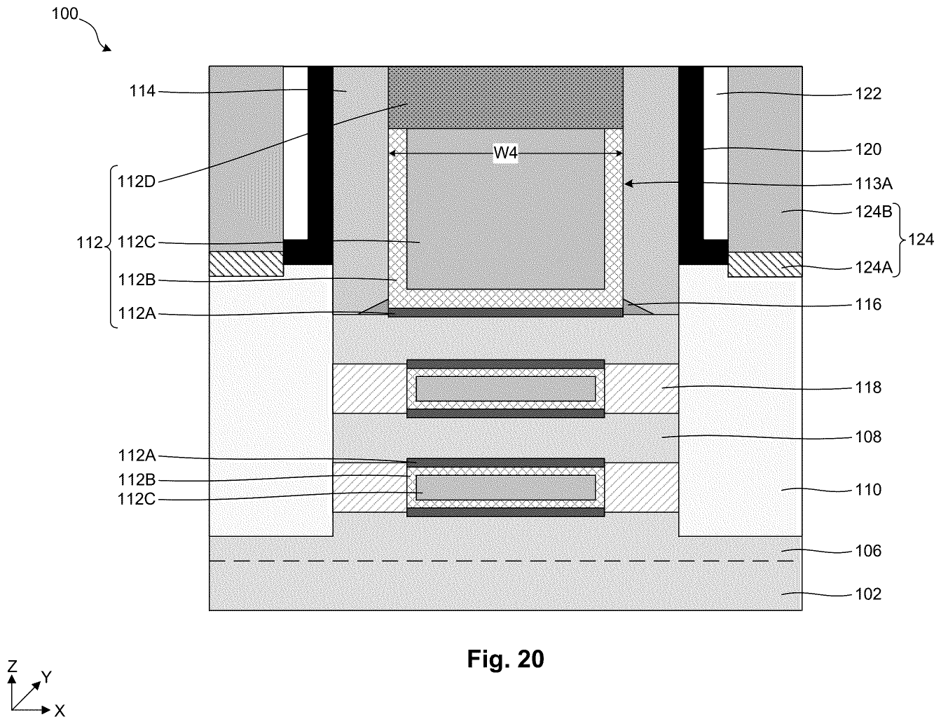

Referring to FIG. 3, in operation 330, a gate structure is formed around the nanostructured layers. For example, as described with reference to FIGS. 18-20, gate structure 112 is formed around nanostructured layers 108. The formation of gate structure 112 can include sequential operations of (i) removing nanostructured sacrificial layers 109 from the structure of FIG. 15, 16, or 17 to form gate openings 1812, (ii) performing an oxidation process on the exposed regions of nanostructured layers 108 in gate openings 912 and 1812 to form IL layers 112A, as shown in FIG. 18, (iii) forming HK gate dielectric layers 112B on IL layers 112A, as shown in FIG. 19, (iv) forming conductive layers 112C on HK gate dielectric layers 112B, as shown in FIG. 19, (v) etching HK gate dielectric layer 112B and conductive layer 112C in outer gate portion 113A, and (vi) forming gate capping layer 112D on HK gate dielectric layer 112B and conductive layer 112C, as shown in FIG. 20. In some embodiments, the formation of gate structure 112 can be followed by the formation of contact structures 124 on S/D regions 110, as shown in FIG. 20.

The present disclosure provides example structures and methods for improving bottom corner profiles of gate structures in FETs to prevent current leakage between gate structures and source/drain (S/D) regions in the FETs. In some embodiments, a FET (e.g., GAA FET 100) can have nanostructured channel regions (e.g., nanostructured channel regions 108) disposed on a substrate, a gate structure (e.g., gate structure 112) disposed around the nanostructured channel regions, S/D regions (e.g., S/D regions 110) disposed adjacent to the nanostructured channel regions, and outer gate spacers (e.g., outer gate spacers 114) disposed along sidewalls of the gate structure to electrically isolate the gate structure from adjacent source/drain regions. In some embodiments, interfacial gaps (e.g., interfacial gaps 1316) can exist between the outer gate spacers and the topmost nanostructured channel regions. These interfacial gaps can be filled with interfacial spacer layers (e.g., interfacial spacer layers 116) having an insulating material. The interfacial spacer layers can prevent bottom corner portions (e.g., bottom corner region 112cr) of the gate structure from being formed in the interfacial gaps during the formation of the gate structure. Preventing bottom corner portions of the gate structure from extending under the outer gate spacers can increase the spacing between the gate structure and adjacent S/D regions, prevent current leakage or minimize the probability of current leakage between the gate structure and adjacent S/D regions, and improve device performance. Thus, with the use of interfacial spacer layers, the bottom corner profiles of the gate structure can be controlled. Depending on the sidewall profiles (e.g., right-angled profiles of sidewalls 116s1, sloped profiles of sidewalls 116s2, and curved profiles of sidewalls 116s3) of the interfacial spacer layers, the gate structure can have a U-shaped cross-sectional profile with bottom corners having right-angled corner profiles, beveled corner profiles, or rounded corner profiles.

In some embodiments, a semiconductor device includes a substrate, a semiconductor layer disposed on the substrate, a S/D region disposed adjacent to the semiconductor layer, a gate structure disposed on the semiconductor layer, an interfacial spacer layer having a triangular cross-sectional profile disposed along a sidewall of the gate structure, and a gate spacer. The gate spacer includes a first spacer portion having a first bottom surface with a substantially linear profile disposed on the semiconductor layer and a second spacer portion having a second bottom surface with a sloped profile disposed on the interfacial spacer layer.

In some embodiments, a semiconductor device includes a substrate, a fin structure disposed on the substrate, a gate structure disposed on the fin structure, a gate spacer disposed along a sidewall of the gate structure, and an interfacial spacer layer. The interfacial spacer layer includes a first sidewall with a sloped profile facing a bottom surface of the spacer, a second sidewall facing the sidewall of the gate structure, and a bottom surface facing a top surface of the fin structure.

In some embodiments, a method includes forming an oxide layer on a semiconductor layer, forming a polysilicon structure on the oxide layer, forming a gate spacer on the oxide layer and the polysilicon structure, forming a gate opening by removing the polysilicon structure, forming an interfacial spacer layer between a bottom surface of the gate spacer and a top surface of the semiconductor layer, and forming a gate structure in the gate opening and in contact with the interfacial spacer layer and the gate spacer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate;
a semiconductor layer disposed on the substrate;
a source/drain region disposed adjacent to the semiconductor layer;
a gate structure disposed on the semiconductor layer;
an interfacial spacer layer comprising a triangular cross-sectional profile disposed along a sidewall of the gate structure; and
a gate spacer, comprising:
a first spacer portion comprising a first bottom surface with a substantially linear profile disposed on the semiconductor layer; and
a second spacer portion comprising a second bottom surface with a sloped profile disposed on the interfacial spacer layer.

2. The semiconductor device of claim 1, wherein the interfacial spacer layer comprises a sidewall with a substantially linear profile facing the gate structure.

3. The semiconductor device of claim 1, wherein the interfacial spacer layer comprises a sidewall with a sloped profile facing the gate structure.

4. The semiconductor device of claim 1, wherein the interfacial spacer layer comprises a sidewall with a curved profile facing the gate structure.

5. The semiconductor device of claim 1, wherein the interfacial spacer layer is disposed between the gate spacer and the semiconductor layer.

6. The semiconductor device of claim 1, wherein the interfacial spacer layer comprises an oxide of a material of the gate spacer.

7. The semiconductor device of claim 1, wherein the interfacial spacer layer comprises an oxide of a material of the semiconductor layer.

8. The semiconductor device of claim 1, wherein a bottom corner of the gate structure comprises a beveled corner profile and is in contact with the interfacial spacer layer.

9. The semiconductor device of claim 1, wherein a bottom corner of the gate structure comprises a rounded corner profile and is in contact with the interfacial spacer layer.

10. The semiconductor device of claim 1, wherein the gate structure comprises:
a gate oxide layer in contact with the interfacial spacer layer; and
a gate dielectric layer in contact with the interfacial spacer layer.

11. A semiconductor device, comprising:
a substrate;
a fin structure disposed on the substrate;
a gate structure disposed on the fin structure;
a gate spacer disposed along a sidewall of the gate structure; and
an interfacial spacer layer, comprising:
a first sidewall with a sloped profile facing the gate spacer;
a second sidewall facing the sidewall of the gate structure; and
a bottom surface facing a top surface of the fin structure.

12. The semiconductor device of claim 11, wherein the interfacial spacer layer is disposed between the gate spacer and the fin structure.

13. The semiconductor device of claim 11, wherein the second sidewall comprises a substantially linear profile.

14. The semiconductor device of claim 11, wherein the second sidewall comprises a sloped profile.

15. The semiconductor device of claim 11, wherein the second sidewall comprises a curved profile.

16. The semiconductor device of claim 11, wherein the gate structure comprises:
a gate oxide layer in contact with the interfacial spacer layer; and
a gate dielectric layer in contact with the interfacial spacer layer.

17. A method, comprising:
forming an oxide layer on a semiconductor layer;
forming a polysilicon structure on the oxide layer;
forming a gate spacer on the oxide layer and the polysilicon structure;
forming a gate opening by removing the polysilicon structure;
forming an interfacial spacer layer between a bottom surface of the gate spacer and a top surface of the semiconductor layer; and
forming a gate structure in the gate opening and in contact with the interfacial spacer layer and the gate spacer.

18. The method of claim 17, wherein forming the interfacial spacer layer comprises oxidizing a sidewall of the gate spacer and the top surface of the semiconductor layer.

19. The method of claim 17, wherein forming the interfacial spacer layer comprises exposing an interfacial gap between a bottom surface of the gate spacer and a top surface of the semiconductor layer.

20. The method of claim 19, wherein exposing the interfacial gap comprises etching the oxide layer.
